(19) United States
(12) Patent Application Publication
(10) Pub. No.: US 2002/0039842 A1
(43) Pub. Date: Apr. 4, 2002

(54) Method of increasing oxide/oxynitride etching selectivity ratio in fabrication of self-aligned borderless contact

(76) Inventor: Pei-Humg Chu, Kaohsiung (TW)

Correspondence Address: J. C. Patents, Inc., 4 Venture, Suite 250, Irvine, CA, 92618, US

(21) Appl. No.: 09/727,947

(22) Filed: Dec. 1, 2000

(30) Foreign Application Priority Data
Aug. 15, 2000 (TW) 89116430

(51) Int. Cl. H01L 21/302; H01L 21/461

(52) U.S. Cl. 438/712

(57) ABSTRACT

A method of increasing oxide to oxynitride selectivity ratio inside a magnetically enhanced reactive ion etching chamber when producing a self-aligned borderless contact. The method involves maintaining the cathode inside the magnetically enhanced reactive ion etching chamber at a temperature between 25° C. to 35° C. and preferably at 30° C., supplying 1600 W to 1800 W of power to the reactive ion etching chamber and setting the flow rate of gaseous reactant C₄F₈ to between about 5 sccm to 6 sccm. The invention increases the etching rate of silicon oxide without increasing the etching rate of silicon oxynitride in the process of etching out a self-aligned borderless contact opening.

### CROSS-REFERENCE TO RELATED APPLICATION

This application claims the priority benefit of Taiwan application Ser. No. 89116430, filed Aug. 15, 2000.

### BACKGROUND OF THE INVENTION

1. Field of Invention

The present invention relates to a method of increasing the silicon oxide to silicon oxynitride etching selectivity ratio in the fabrication of a self-aligned borderless contact. More particularly, the present invention relates to a method of increasing the silicon oxide to silicon oxynitride etching selectivity ratio inside a magnetically enhanced reactive ion etching (MERIE) chamber in the fabrication of a self-aligned borderless contact.

2. Description of Related Art

At present, the level of integration of semiconductor devices such as dynamic random access memory (DRAM) is increasing at a rate of about four times every three years. Deep submicron semiconductor devices with a line width smaller than 0.18 μm are manufactured quite routinely. To build a large number of semiconductor devices within the limited surface of a silicon chip, the production of a borderless contact that overlaps over a silicon substrate and an insulating shallow trench is inevitable. To fabricate a borderless contact, an insulating shallow trench is formed over a silicon substrate. A thick (about 500 Å) layer of silicon oxynitride (SiON) is deposited over the insulating trench. A silicon oxide layer is formed over the silicon oxynitride layer. Finally, the silicon oxide layer is etched to form an opening using the silicon oxynitride layer as an etching stop layer.

However, if the silicon oxynitride layer is not strong enough to resist chemical reaction with the etchants in the process of forming an opening in the silicon oxide layer, over-etching may occur. Consequently, the insulating trench close to the silicon substrate may react too much to cause punchthrough and subsequent current leakage o into the substrate when a threshold voltage is applied to the transistor so formed. Such occurrences may lower product yield and reliability. In addition, the etching selectivity ratio between the silicon oxide layer and the silicon oxynitride layer must be increased when a hole having a diameter smaller than 0.3 μm or a contact with an aspect ratio greater than three is fabricated. In other words, the capacity of the silicon oxynitride layer to stop the etching must be increased to prevent punchthrough.

In general, a self-aligned borderless contact opening may form in the silicon oxide layer by etching inside a magnetically enhanced reactive ion etching (MERIE) chamber. However, test results show that temperature of the cathode inside the MERIE chamber has a critical effect on the etching selectivity ratio between the silicon oxide layer and the silicon oxynitride layer. If the cathode temperature is too high, a high-molecular-weight polymer film may be produced in the reaction impeding the etching reaction. On the contrary, if the cathode temperature is too low, the reaction may concentrate on the silicon oxynitride layer leading to possible punchthrough and other leakage problems.

### SUMMARY OF THE INVENTION

Accordingly, one object of the present invention is to provide an etching method for producing a self-aligned borderless contact opening having a high oxide to oxynitride selectivity ratio and a high etching rate, yet capable of preventing punchthrough.

To achieve these and other advantages and in accordance with the purpose of the invention, as embodied and broadly described herein, the invention provides a method of increasing oxide to oxynitride selectivity ratio inside a magnetically enhanced reactive ion etching chamber when producing a self-aligned borderless contact. The method includes maintaining the cathode inside the magnetically enhanced reactive ion etching chamber at a temperature between 25° C. to 35° C. and preferably at 30° C., supplying 1600 W to 1800 W of power to the reactive ion etching chamber and setting the flow rate of gaseous reactant C₄F₈ into the reactive ion etching chamber between about 5 sccm to 6 sccm.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIG. 1 is a sketch of a magnetically enhanced reactive ion etching chamber tailored to the design of this invention;

FIG. 2 is a cross-sectional view showing the structure before the silicon oxide layer is etched to form a self-aligned borderless contact opening; and

FIG. 3 is a cross-sectional view of the self-aligned borderless contact opening after the silicon oxide layer shown in FIG. 2 is etched according to this invention.

### DESCRIPTION OF THE PREFERRED EMBODIMENTS

Reference will now be made in detail to the present preferred embodiments of o the invention, examples of which are illustrated in the accompanying drawings. Wherever possible, the same reference numbers are used in the drawings and the description to refer to the same or like parts.

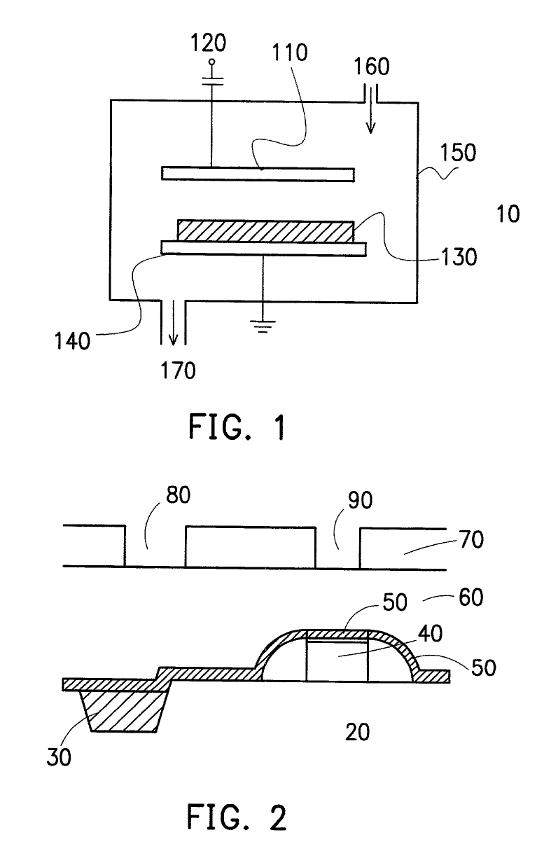

FIG. 1 is a sketch of a magnetically enhanced reactive ion etching (MERIE) chamber tailored to the design of this invention. As shown in FIG. 1, the reaction chamber 10 includes an anode 110, a cathode 140 and chamber walls 150. The anode 110 is connected to a radio frequency (RF) generator 120. A silicon chip 130 is placed on the cathode 140. The cathode 140 and the reaction walls 150 are connected to the ground. A gaseous etchant enters the reaction chamber 10 through an inlet port 160. The gaseous etchant molecules are dissociated by radio frequency into ions. Ions wandering into the region between the anode 110 and the cathode 140 are accelerated by the electric potential between the two electrodes 110 and 140. These accelerated ions bombard on the chip 130, and gaseous products of reaction are exhausted through an outlet port 170.

FIG. 2 is a cross-sectional view showing the structure before the silicon oxide layer is etched to form a self-aligned borderless contact opening. As shown in FIG. 2, an insulating shallow trench 30 is formed in a silicon substrate 20. The gate 40 of a transistor is formed over the substrate 20. A silicon oxynitride layer 50 having a thickness of about 500 Å is formed over the substrate 20, the insulating trench 30 and the gate 40 of the transistor. The silicon oxynitride layer 50 serves as a self-aligned etching stop layer. Silicon oxide is deposited over the silicon oxynitride layer 50 to form a silicon oxide layer 60. Photoresist material is deposited over the silicon oxide layer 60 and then patterned to form a patterned photoresist layer 70 having a pair of openings 80 and 90.

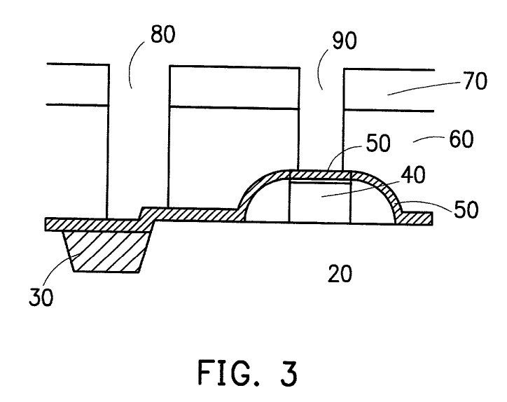

FIG. 3 is a cross-sectional view of the self-aligned borderless contact opening after the silicon oxide layer shown in FIG. 2 is etched according to this invention. As shown in FIG. 3, the opening 80 is formed above a region overlapping the substrate 20 and the shallow trench 30. The opening 90 is formed in a region above the gate 40 of the transistor so that device density can be increased. The openings 80 and 90 preferably end at the silicon oxynitride layer 50. The silicon oxynitride etching reaction is a slightly exothermic reaction. If the temperature of the chip 130 is too low during reaction, (in other words, if temperature of the cathode 140 is too low) the etching rate of the silicon oxynitride layer 50 will increase. Hence, a considerable fraction of the reactive ion etching will occur in the silicon oxynitride layer 50 leading to possible punchthrough and related reliability problems, including current leakage when applying a threshold voltage to the ultimately formed transistor. Consequently, lowering the temperature of cathode 140 can reduce the etching rate for the silicon oxynitride layer 50 so that most etching reactions occur in the oxide layer 60. Therefore, the overall etching selectivity ratio between the oxide layer 60 and the oxynitride layer 50 is increased. However, the temperature of the cathode 140 must not be too high, above 40° C., for example. At a high temperature, a high-molecular-weight carbon-based polymer that impedes the etching reaction may form due to the presence of carbon-based and fluorine-based gaseous reactants. The effect of high temperature is most pronounced when etching small diameter holes (smaller than 0.3 μm) or holes having an aspect ratio greater than 3. Thus, the temperature of the cathode 140 during the etching reaction must be carefully set.

In the aforementioned self-aligned borderless contact etching, the reaction is carried out using gases including C₄F₈, CF₄, CO and Ar. In addition, the following parameters are set including: a power rating of 1600 W˜1800 W, a reaction chamber pressure of 75 mT˜85 mT, a magnetic field of about 20 G, a gas flow rate for C₄F₈ of 5 sccm˜6 sccm, a gas flow rate for CO of about 220 sccm, a gas flow rate for Ar of about 100 sccm, a reaction chamber wall temperature of about 15° C. and a cathode temperature of 25° C. 35° C. Table 1 lists the results of oxide etching obtained under various etching conditions. As shown in Table 1, the etching selectivity ratio between the oxide layer 60 and the oxynitride layer 50 depends critically upon the temperature of the cathode. When the temperature of the cathode is about 30° C., the gas flow rate for C₄F₈ is about 6 sccm and the reaction chamber pressure is about 75 mT, the average consumption of the silicon oxynitride layer 50 is the lowest. Meanwhile, the etching selectivity ratio between the oxide layer 60 and the oxynitride layer 50 is the highest at about 35.

In brief, the method of the invention is capable of increasing the etching selectivity ratio between oxide material and oxynitride material. Hence, punchthrough of the silicon oxynitride layer in the process of forming a self-aligned borderless contact by etching can be prevented.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

TABLE 1

| | | Reaction | | Average | Etching Selectivity |
|---|---|---|---|---|---|
| | C₄F₈ | Chamber | Cathode | Wasting of | Ratio Between Oxide |
| Test | Flow Rate | Pressure | Temperature | Oxynitride | Material and |
| no. | (sccm) | (mT) | (° C.) | material | Oxynitride Meterial |
| 1 | 5 | 75 | 15 | 194 | 23 |
| 2 | 5 | 85 | 30 | 145 | 31 |
| 3 | 6 | 75 | 30 | 130 | 35 |

What is claimed is:

1. A method for increasing the etching selectivity ratio between oxide and oxynitride inside a magnetically enhanced reactive ion etching chamber in the process of forming a self-aligned borderless contact, comprising the steps of:
maintaining a cathode inside the reactive ion etching chamber at a working temperature;
providing a preset level of power to the reactive ion etching chamber;
and
setting up a definite rate of flow of a gaseous reactant C₄F₈ into the reactive ion etching chamber.

2. The method of claim 1, wherein the step of maintaining a working temperature for the cathode includes controlling the cathode at a temperature between 25° C. to 35° C.

3. The method of claim 1, wherein the step of providing a preset level of power to the reactive ion etching chamber includes supplying between 1600 W to 1800 W of power.

4. The method of claim 1, wherein the step of setting the flow rate of C₄F₈ includes supplying the reactive ion etching chamber with the gas at a rate of 5 sccm to 6 sccm.

5. A method for increasing the etching selectivity ratio between an oxide layer and an oxynitride layer inside a magnetically enhanced reactive ion etching chamber in the process of forming a self-aligned borderless contact, comprising the steps of:
maintaining a cathode inside the reactive ion chamber at a working temperature of between about 25° C. to 35° C.;
setting a power rating of the reactive ion etching chamber to between about 1600 W to 1800 W;
setting a flow rate of a gaseous reactant C₄F₈ into the reactive ion etching chamber to between about 5 sccm to 6 sccm;
setting a pressure inside the reactive ion etching chamber to between about 75 mT to 85 mT;
setting a magnetic field inside the reactive ion etching chamber to between about 15 G to 25 G;
setting a flow rate of a gaseous reactant CO into the reactive ion etching chamber to between about 150 sccm to 250 sccm;
setting a flow rate of a gaseous stabilizer Ar into the reactive ion etching chamber to between 50 sccm to 150 sccm; and
setting temperature of a wall of the reactive ion etching chamber to between about 10° C. to 20° C.
